(19) United States
(12) Patent Application Publication
(10) Pub. No.: US 2010/0329027 A1
(43) Pub. Date: Dec. 30, 2010

(54) NONVOLATILE MEMORY DEVICE AND METHOD OF OPERATING THE SAME

(76) Inventor: Won Kyung KANG, Seoul (KR)

Correspondence Address: IP & T GROUP LLP, 7700 Little River Turnpike, Suite 207, Annandale, VA, 22003, US

(21) Appl. No.: 12/763,471

(22) Filed: Apr. 20, 2010

(30) Foreign Application Priority Data
Jun. 30, 2009 (KR) 10-2009-0059163

(51) Int. Cl. G11C 16/06; G11C 16/04

(52) U.S. Cl. 365/185.22; 365/185.18

(57) ABSTRACT

A nonvolatile memory device includes a control unit configured to output operation signals, including an operation command signal, a source address, a destination address, and a data signal, to each of a number of memory chips in order to operate the memory chips, a command decoder configured to decode the command signal and generate operation command information, a source address controller configured to generate source address information based on the source address, a destination address controller configured to generate destination address information based on the destination address, a chip controller configured to generate a command enable signal based on the operation command information, the source address information, and the destination address information, and a data controller configured to operate a memory cell array in response to the data signal and the command enable signal.

### CROSS-REFERENCE TO RELATED APPLICATION

Priority to Korean patent application number 10-2009-0059163 filed on Jun. 30, 2009, the entire disclosure of which is incorporated by reference herein, is claimed.

### BACKGROUND

Exemplary embodiments relate to a nonvolatile memory device and a method of operating the same, and more particularly, to a nonvolatile memory device, including a number of memory chips and a method of operating the same.

With a reduction in the size and an increase in the capacity of memory products, the degree of integration of nonvolatile memory devices is being increased to store more data. To this end, a number of memory chips may be formed in one package.

In the case in which a number of the memory chips are included in one package, the memory chips are operated by a control unit included within the package and disposed outside of the memory chips. The control unit controls the operations of a selected memory chip, such as program, reading, erasure, and copy operations. In general, while one chip is selected and performing an operation, the remaining chips are not performing an operation. For example, when a selected memory chip is in an operation state, the remaining memory chips can be in an idle state because the control unit controls the operations of the selected memory chip.

The operations of a memory chip can include a program operation, an erase operation, a read operation, and a copyback operation. Here, the copyback operation is used to copy data, stored in a memory cell (i.e., a source), to another memory cell (i.e., a destination). In particular, in the case in which the copyback operation is performed for every cell block, all data stored in a cell block (i.e., a source) must be copied to a cell block (i.e., a destination). Thus, the time that it takes to perform the copyback operation is longer than the time that it takes to perform other operations, such as a program, erase, or read operation.

The operational efficiency is low, because while a selected one of the memory chips included in the package is performing an operation, the remaining memory chips are not performing an operation.

### BRIEF SUMMARY

According to exemplary embodiments, in a package including a number of memory chips, each of the memory chips is operated in response to an operation command signal. Accordingly, all the memory chips can be operated at the same time.

A nonvolatile memory device according to an aspect of the present disclosure includes a control unit configured to output operation signals, including an operation command signal, a source address, a destination address, and a data signal, to each of a number of memory chips in order to operate the memory chips, a command decoder configured to decode the command signal and generate operation command information, a source address controller configured to generate source address information based on the source address, a destination address controller configured to generate destination address information based on the destination address, a chip controller configured to generate a command enable signal based on the operation command information, the source address information, and the destination address information, and a data controller configured to operate a memory cell array in response to the data signal and the command enable signal.

The control unit may output one of the operation signals to a selected one of the memory chips and output another of the operation signals to another of the memory chips at or before a time when an operation of the selected memory chip is completed.

The control unit may generate a program operation command signal, the destination address, and the data signal as the operation signals when a program operation is performed.

The control unit may generate an erase operation command signal and the destination address as the operation signals when an erase operation is performed.

The control unit may generate a read operation command signal and the source address as the operation signals when a read operation is performed.

While the selected one of the memory chips is operating, the control unit may output one of the operation signals to another of the memory chips.

A method of operating a nonvolatile memory device according to another aspect of the present disclosure includes inputting operation signals, including a first operation command, a source address, a second operation command, and a destination address, to a selected one of a number of memory chips, performing an erase operation on a destination block included in the selected memory chip, and performing a copyback operation for copying data of a source block, included in the selected memory chip, to the destination block.

When the copyback operation is performed on a block basis, the first operation command is a read operation command, and the second operation command is a program operation command.

A method of operating a nonvolatile memory device according to yet another aspect of the present disclosure includes inputting operation signals, including a first operation command and a destination address, to a selected one of a number of memory chips, performing an erase operation on a selected destination block of the selected memory chip based on the destination address, and performing a program operation on the destination block that has been erased.

The method may further include performing a program verification operation after performing the program operation.

A method of operating a nonvolatile memory device according to yet another aspect of the present disclosure includes inputting operation signals, including a first operation command and a destination address, to a selected one of a number of memory chips and performing an erase operation on a selected destination block of the selected memory chip based on the destination address.

The method may further include performing an erase verification operation after performing the erase operation.

A method of operating a nonvolatile memory device according to yet another aspect of the present disclosure comprises inputting operation signals, including a first operation command and a source address, to a selected one of a number of memory chips and performing a read operation on a selected source block of the selected memory chip based on the source address.

The method may further include performing a read verification operation after performing the read operation.

### BRIEF DESCRIPTION OF THE DRAWINGS

FIG. 1 is a diagram illustrating a nonvolatile memory device and a method of operating the same according to the present disclosure;

FIG. 2 is a diagram of one of the memory chips shown in FIG. 1; and

FIG. 3 is a flowchart illustrating a method of performing a copyback operation according to an embodiment of the present disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

FIG. 1 is a diagram illustrating a nonvolatile memory device and a method of operating the same according to the present disclosure.

The nonvolatile memory device includes a number of memory chips CH1 to CHn for storing data and a control unit 110 for controlling the memory chips CH1 to CHn, where n is a positive integer. The memory chips CH1 to CHn and the control unit 110 are included in one package 100.

The control unit 110 receives an external I/O signal I/O from outside of the package 100, and outputs any of operation signals L1 to Ln to a selected one of the memory chips CH1 to CHn. In particular, while the selected memory chip is in an operation, the control unit 110 can select any of the other memory chips and output any of the operation signals L1 to Ln to the other memory chips. For example, after outputting any one of the operation signals L1 to Ln to the selected memory chip, the control unit 110 can select another memory chip and output any one of the operation signals L1 to Ln to the other memory chip, while not monitoring the operations of the selected memory chip from start to end.

After the operations of the selected memory chip are completed, the control unit 110 receives an operation completion signal from the selected memory chip.

The memory chips CH1 to CHn perform corresponding operations in response to the respective operation signals L1 to Ln generated by the control unit 110. In particular, each of the memory chips CH1 to CHn performs program, erase, and read operations in response to the operation signals L1 to Ln, respectively. The program, erase, and read operations are monitored within each memory chip. After the corresponding operation is completed, the corresponding memory chip outputs the operation signal (one of L1 to Ln), indicating the completion of the corresponding operation, to the control unit 110. To this end, each of the memory chips includes internal circuits for controlling the operations of the corresponding memory chip in response to the operation signal (one of L1 to Ln).

However, in the case in which a copyback operation performed for every cell block is selected while the nonvolatile memory device is operated, the time that it takes to perform the copyback operation is longer than the time that it takes to perform an operation of programming data into a selected cell, an operation of erasing a selected block, or an operation of reading data stored in a selected cell.

In more detail, each of cell blocks BLa and BLb (only two cell blocks are illustrated in FIG. 1 for sake of convenience) includes a number of pages. Each of the pages includes a number of cells. More specifically, a page is the unit representing a group of cells coupled to a word line.

After an erase operation is performed on all the cells of a destination block (for example, herein BUD is a destination block) to which data will be copied, the copyback operation can be performed by reading data from a source block (for example, herein BLa is a source block) on a page basis and programming the read data into a selected page of the destination block BUD. The operation of programming the read data into the destination block BLb is performed by repeatedly performing a program operation and a program verification operation. The copyback operation, performed on a block basis as described above requires more time because data have to be read from all the pages of the source cell block BLa, and then programmed into all the pages of the destination block BLb.

While the copyback operation is performed on a selected memory chip on a block basis as described above, if the operation of the other memory chips can be controlled, an overall operation time of the nonvolatile memory device can be reduced. Here, the operation of the other memory chips can include a program, erase, or read operation, or a copyback operation of a block unit. According to an exemplary embodiment of this disclosure, one or more of the memory chips CH1 to CHn included in the package 100 can be selected for performing an operation.

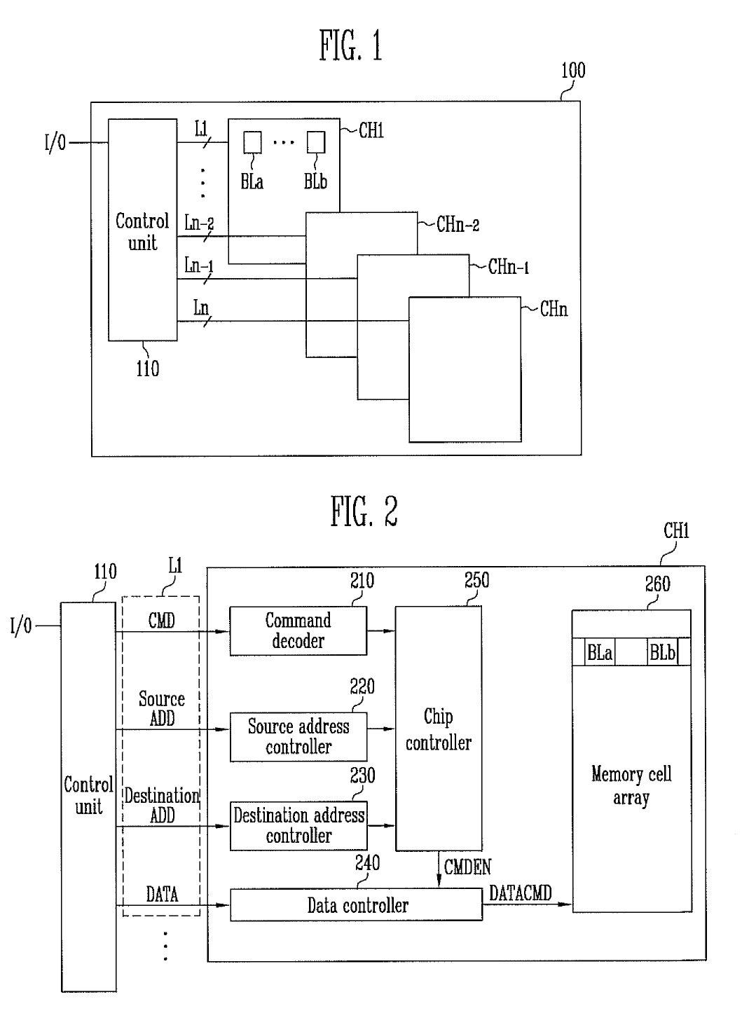

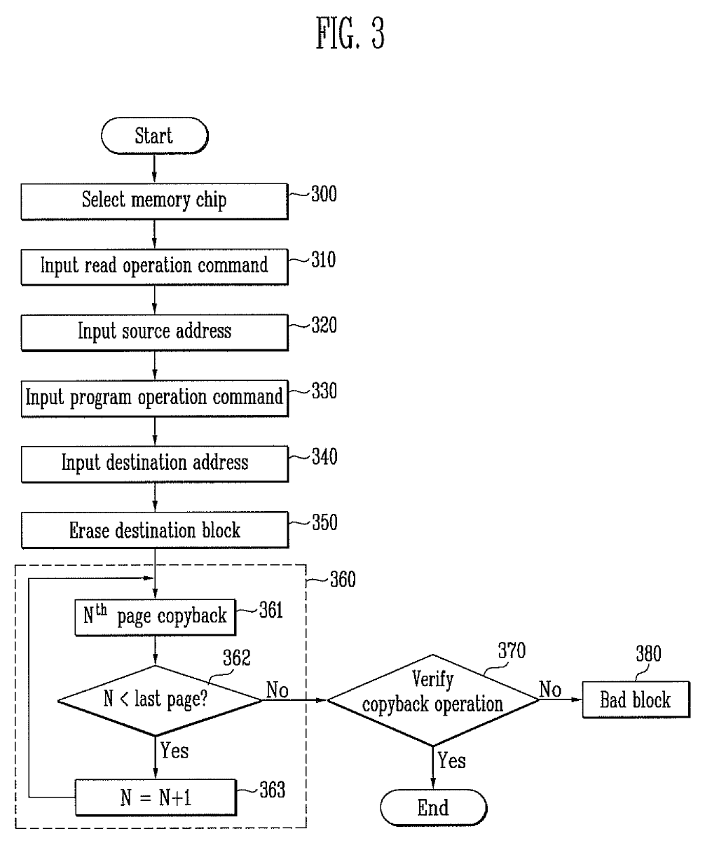

FIG. 2 is a diagram of one of the memory chips shown in FIG. 1. The memory chips preferably have the same structure. The control unit 110 and one (e.g., CH1) of the memory chips CH1 to CHn are described in more detail below.

Referring to FIGS. 1 and 2, when the first memory chip CH1 is selected, the control unit 110 outputs a first operation signal L1, including an operation command signal CMD, a source address ADD, a destination address ADD, and a data signal DATA, to the first memory chip CH1.

The first memory chip CH1 includes internal circuits, including a command decoder 210, a source address controller 220, a destination address controller 230, a data controller 240, a chip controller 250, and a memory cell array 260.

The command decoder 210 receives the operation command signal CMD from the control unit 110, decodes the received operation command signal CMD, and outputs the decoded signal to the chip controller 250.

The source address controller 220 receives the source address ADD from the control unit 110 and transfers the received source address ADD to the chip controller 250. For example, when a copyback operation is performed, the address of a block (i.e., a source in which data are stored) can be transferred to the chip controller 250.

The destination address controller 230 receives the destination address ADD from the control unit 110 and transfers the received destination address ADD to the chip controller 250. For example, when a copyback operation is performed, the address of a block (i.e., a destination in which data will be stored) can be transferred to the chip controller 250.

The data controller 240 receives the data signal

DATA from the control unit 110 and a command enable signal CMDEN from the chip controller 250 and generates a buffered data transfer signal DATACMD based on the received signals.

The chip controller 250 generates the command enable signal CMDEN for controlling the data controller 240, in response to the signals received from the command decoder 210 and the source and destination address controllers 220 and 230.

The memory cell array 260 is operated in response to the data transfer signal DATACMD and is configured to perform a program operation, an erase operation, or a read operation on memory cells included in the memory cell array 260.

A copyback operation performed on a block basis, from among the operations of the nonvolatile memory device according to the exemplary embodiment of the present disclosure, is described below.

FIG. 3 is a flowchart illustrating a method of performing a copyback operation according to an embodiment of the present disclosure.

The copyback operation includes a memory chip selection step 300, a read operation command input step 310, a source address input step 320, a program operation command input step 330, a destination address input step 340, a destination block erase step 350, a copyback operation step 360, and a copyback operation verification step 370.

The method of performing the copyback operation is described below in more detail with reference to FIGS. 2 and 3.

In the memory chip selection step 300, a memory chip on which the copyback operation will be performed is selected based on an external input chip address. In more detail, the control unit 110 determines whether the external input chip address is identical with an address of the corresponding memory chip, and if the external input chip address is identical with the address of the corresponding chip, the control unit 110 outputs an enable signal to the selected memory chip and outputs signals for operations to the memory chip. It is hereinafter assumed that the first memory chip CH1 has been selected.

The copyback operation refers to an operation of copying data from a source block in which the data are stored to a destination block in which the data will be stored. The copyback operation is performed to copy data from all pages within the source block to all pages within the destination block. For example, after data are read from the source block by performing a read operation, the read data can be programmed into the destination block by performing a program operation. To this end, a corresponding operation command and information about source and destination addresses are inputted.

In the read operation command input step 310, the command decoder 210 receives a read operation command from the control unit 110.

In the source address input step 320, the source address controller 220 receives an address, corresponding to the source block, from the control unit 110.

In the program operation command input step 330, the command decoder 210 receives a program command from the control unit 110.

In the destination address input step 340, the destination address controller 230 receives an address, corresponding to the destination block, from the control unit 110.

In the destination block erase step 350, an erase operation is performed on all the memory cells included in the destination block BLb in which data will be stored. In more detail, the chip controller 250 outputs the command enable signal CMDEN for the erase operation to the data controller 240 in response to the operation command, received from the command decoder 210, and the address of the destination block BLD received from the destination address controller 230. In response to the command enable signal CMDEN, the data controller 240 outputs the data transfer signal DATACMD to the memory cell array 260 so that the erase operation is performed on the destination block BLb.

In the copyback operation step 360, the copyback operation from the source block BLa to the destination block BLb is performed on a page basis. In more detail, the copyback operation step 360 includes an N^{th} page copyback step 361 and a last page check step 362. If a selected page is not the last page in the last page check step 362, a page number N is increased at step 363, and the process returns to step 361 in which the copyback operation is repeatedly performed until the page number N becomes the number of the last page.

The copyback operation is performed on a page basis as follows. First, data stored in memory cells included in the first page of the source block BLa are read and stored in a page buffer (not shown) of the memory cell array. The data stored in the page buffer (not shown) are programmed into memory cells included in the first page of the destination block BLb.

In the copyback operation verification step 370, it is verified whether the data stored in the source block BLa are all copied to the destination block BLb. For example, data stored in the destination block BLb can be compared with the data stored in the source block BLa. If, as a result of the comparison, the data stored in the destination block BLb are identical with the data stored in the source block BLa, the copyback operation is completed. However, if, as a result of the comparison, the data stored in the destination block BLb are not identical with the data stored in the source block BLa, the destination block BLb is treated as being a bad block at step 380. Next, another destination block is selected, and the copyback operation is performed on that selected destination block.

As described above, while each of the memory chips internally controls its operations, the control unit 110 provided outside of the memory chips can select and operate another memory chip. Accordingly, the time that it takes to operate a nonvolatile memory device can be reduced because a number of memory chips included in the nonvolatile memory device within a package can be operated. Consequently, the operation speed of the nonvolatile memory device can be increased.

What is claimed is:

1. A nonvolatile memory device, comprising:
a control unit configured to output operation signals including an operation command signal, a source address, a destination address, and a data signal to each of a number of memory chips in order to operate the memory chips;
a command decoder configured to decode the command signal and generate operation command information;
a source address controller configured to generate source address information based on the source address;
a destination address controller configured to generate destination address information based on the destination address;
a chip controller configured to generate a command enable signal based on the operation command information, the source address information, and the destination address information; and
a data controller configured to operate a memory cell array in response to the data signal and the command enable signal.

2. The nonvolatile memory device of claim 1, wherein the control unit outputs one of the operation signals to a selected one of the memory chips and outputs another of the operation signals to another of the memory chips at or before a time when an operation of the selected memory chip is completed.

3. The nonvolatile memory device of claim 1, wherein the control unit generates a program operation command signal, the destination address, and the data signal as the operation signals when a program operation is performed.

4. The nonvolatile memory device of claim 1, wherein the control unit generates an erase operation command signal and the destination address as the operation signals when an erase operation is performed.

5. The nonvolatile memory device of claim 1, wherein the control unit generates a read operation command signal and the source address as the operation signals when a read operation is performed.

6. The nonvolatile memory device of claim 1, wherein the control unit outputs one of the operation signals to another of the memory chips, while a selected one of the memory chips is operating.

7. A method of operating a nonvolatile memory device, the method comprising:
inputting operation signals, including a first operation command, a source address, a second operation command, and a destination address, to a selected one of a number of memory chips;
performing an erase operation on a destination block included in the selected memory chip; and
performing a copyback operation for copying data of a source block, included in the selected memory chip, to the destination block.

8. The method of claim 7, wherein when the copyback operation is performed on a block basis, the first operation command is a read operation command, and the second operation command is a program operation command.

9. A method of operating a nonvolatile memory device, the method comprising:
inputting operation signals, including a first operation command and a destination address, to a selected one of a number of memory chips;
performing an erase operation on a selected destination block of the selected memory chip based on the destination address; and
performing a program operation on the destination block that has been erased.

10. The method of claim 9, further comprising performing a program verification operation after performing the program operation.

11. A method of operating a nonvolatile memory device, the method comprising:
inputting operation signals, including a first operation command and a destination address, to a selected one of a number of memory chips; and
performing an erase operation on a selected destination block of the selected memory chip based on the destination address.

12. The method of claim 11, further comprising performing an erase verification operation after performing the erase operation.

13. A method of operating a nonvolatile memory device, the method comprising:
inputting operation signals, including a first operation command and a source address, to a selected one of a number of memory chips; and
performing a read operation on a selected source block of the selected memory chip based on the source address.

14. The method of claim 13, further comprising performing a read verification operation after performing the read operation.
